(19) United States
(12) Patent Application Publication
(10) Pub. No.: US 2026/0173844 A1
(43) Pub. Date: Jun. 18, 2026

(54) TIP TO TIP DISTANCE PRESERVATION AT ZERO TRACK SKIP

(71) Applicant: INTERNATIONAL BUSINESS MACHINES CORPORATION, Armonk, NY (US)

(72) Inventors: Kishore Natarajan, Albany, NY (US); Shravana Kumar Katakam, Lehi, UT (US); Ruilong Xie, Niskayuna, NY (US); Yann Mignot, Slingerlands, NY (US); Chih-Chao Yang, Glenmont, NY (US)

(21) Appl. No.: 18/984,205

(22) Filed: Dec. 17, 2024

(51) Int. Cl. H01L 23/522; H01L 21/768; H01L 23/528

(52) U.S. Cl. CPC H10W 20/42; H10W 20/057; H10W 20/063; H10W 20/43

(57) ABSTRACT

A semiconductor device includes a first metal level including first metal lines and a second metal level including second metal lines. A via level is disposed between the first metal level and the second metal level. The via level includes a first dielectric layer on the first metal lines, a second dielectric layer on the first dielectric layer and vias having different widths respectively through the first dielectric layer and the second dielectric layer to connect the first metal lines to the second metal lines. The second metal lines include end portions separated by a dielectric pillar, the dielectric pillar including a width between the end portions to reduce short circuits.

### BACKGROUND

The present invention generally relates to semiconductor devices and processing methods, and more particularly to metal structures preserving tip-to-tip distance between metal lines with zero track skip conditions.

Semiconductor devices include metal structures that can have a number of parallel metal lines connected to metal lines in other layers using vias. In some instances, it is beneficial to have metal lines terminate or be separated along their length. This break in a metal line forms two collinear metal lines of lesser length. A gap between these metal lines is filled with a dielectric material. The dielectric material, called a zero track skip, is defined and bounded by the adjacent metal lines.

The two collinear metal lines of lesser length can be connected to vias in underlying layers. These vias can connect to each of the adjacent ends of the two collinear metal lines of lesser length. A space between these vias can be referred to as a tip-to-tip (T2T) spacing. In conventional devices where metal lines include a zero track skip, a tip-to-tip spacing can be extremely tight between these vias, especially given ever decreasing node sizes. This means that sufficient space needed to prevent shorting is close to unacceptable margins.

The zero track skip needs to provide sufficient isolation between ends of metal lines and fit within a tip-to-tip spacing of the underlying vias. In addition, the metal lines need to make reliable connections with the vias in this narrow region.

### SUMMARY

In accordance with an embodiment of the present invention, a semiconductor device includes a first metal level including first metal lines and a second metal level including second metal lines. A via level is disposed between the first metal level and the second metal level. The via level includes a first dielectric layer on the first metal lines, a second dielectric layer on the first dielectric layer and vias having different widths respectively through the first dielectric layer and the second dielectric layer to connect the first metal lines to the second metal lines. The second metal lines include end portions separated by a dielectric pillar, the dielectric pillar including a width between the end portions to reduce short circuits.

In accordance with another embodiment of the present invention, a semiconductor device includes a first metal level including first metal lines and a second metal level including second metal lines. A via level is disposed between the first metal level and the second metal level. The via level includes a first dielectric layer on the first metal lines, a second dielectric layer on the first dielectric layer and vias extending through the first dielectric layer and the second dielectric layer. The vias include a top portion in the second dielectric layer having a first width and a bottom portion in the first dielectric layer having a second width, the second width being greater than the first width. The second metal lines include end portions separated by a dielectric pillar.

In accordance with another embodiment of the present invention, a semiconductor device includes a first metal level including first metal lines, a second metal level including second metal lines and a via level between the first metal level and the second metal level. The via level includes a first dielectric layer on the first metal lines, a second dielectric layer on the first dielectric layer and linerless vias extending through the first dielectric layer and the second dielectric layer. The linerless vias include a top portion in the second dielectric layer having a first width and a bottom portion in the first dielectric layer having a second width, the second width being greater than the first width. The bottom portion directly contacts a top surface of one of the first metal lines. The second metal lines include end portions separated by a dielectric pillar, the dielectric pillar having a width between the end portions.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a cross-sectional view of a substrate and a metal level having metal lines formed thereon after depositing a dielectric material, in accordance with an embodiment of the present invention;

FIG. 2 shows a cross-sectional view after forming a first dielectric layer and a second dielectric layer over the metal lines, in accordance with an embodiment of the present invention;

FIG. 3 shows a cross-sectional view after forming an interlayer dielectric over the second dielectric layer, in accordance with an embodiment of the present invention;

FIG. 4 shows a cross-sectional view after forming trenches for metal lines in the interlayer dielectric to form a dielectric pillar (zero track skip), in accordance with an embodiment of the present invention;

FIG. 5 shows a cross-sectional view after patterning a self-aligned via opening in the second dielectric layer, in accordance with an embodiment of the present invention;

FIG. 6 shows a cross-sectional view after extending the via openings into the first dielectric layer, in accordance with an embodiment of the present invention;

FIG. 7 shows a cross-sectional view after isotropic etching the via openings to form different width portions, in accordance with an embodiment of the present invention;

FIG. 8 shows a cross-sectional view after selective deposition of vias, which further extend into the trenches for metal lines, in accordance with an embodiment of the present invention; and

FIG. 9 shows a cross-sectional view after depositing material for forming metal lines, in accordance with an embodiment of the present invention.

### DETAILED DESCRIPTION

In accordance with embodiments of the present invention, devices and methods are described which include zero track skips that are disposed between metal lines. These metal lines are separated by a gap between their end portions. The gap that separates the end portions of the metal lines needs to have an adequate distance to prevent short circuiting. However, the gap distance between the metal lines is limited as it is controlled by a pitch of underlying metal structures. As an example, if the metal lines separated by the gap are on a metal level of Mx+1, the metal lines separated by the gap can connect to underlying metal lines on a metal level Mx by vias on a metal level Vx formed between the metal lines on Mx and Mx+1. As Mx pitch decreases, the tip-to-tip (T2T) distance between end portions of the metal lines on Mx+1 becomes a concern if Mx+1 does not skip any Mx track (zero track skip).

Embodiments of the present invention include an interconnect structure that has a first dielectric layer and a second dielectric formed over metal lines on the Mx level. A linerless via is formed over the metal lines in the Mx metal level, having a first width portion in the second dielectric layer and a second width portion in the first dielectric layer, where second width portion has a greater width than the second width portion. The linerless via includes a top surface that can partially extend into Mx+1 metal level. The first dielectric layer and the second dielectric layer can include different materials. The linerless vias in metal level Vx can be directly formed on the metal lines of the Mx metal level (e.g., no metal cap between the metal Ine and the via). The linerless via can include, e.g., Ru or Co. The difference in width permits adjustments in the spacings of the via that can provide sufficient conductivity but also permit enough of a gap between the vias to prevent shorts.

In other embodiments, methods for forming an interconnect structure include forming metal lines on an Mx metal level and depositing a first dielectric layer and a second dielectric layer over the metal lines on the Mx metal level. An interlayer dielectric is formed over the second dielectric layer. Trenches are formed in the interlayer dielectric. The trenches provide a form for separate metal lines (Mx+1 level). A zero track skip includes a portion of the interlayer dielectric between metal line trenches. An etch mask is formed, and self-aligned via openings are etched into the second dielectric layer in accordance with the etch mask. The etching continues to partially etch into the first dielectric layer. Then, another etch, e.g., an isotropic etch, is performed, which is selective to the second dielectric layer to open up a width etched into the first dielectric such that a width of the opening in the first dielectric layer is larger than the width or the opening in the second dielectric layer. Also, a metal cap on the underlying metal lines (Mx level) is removed.

A linerless via is formed by selective growth on the underlying metal lines (Mx). The metal fill of the linerless via fills the openings in the first and second dielectric layers. The metal lines are formed in the Mx+1 level trenches while preserving the portion of the interlayer dielectric (zero track skip) between metal lines trenches to provide adequate dielectric between end portions of the metal lines of the Mx+1 level at a via pitch.

A zero track skip is provided that can reliably be formed and can provide sufficient dielectric spacing while making connections between vias and metal lines. Embodiments in accordance with the present invention enable a zero track skip that can provide full contact between a via and a metal line end. This provides a resistance benefit by reducing electrical resistance between vias and metal lines.

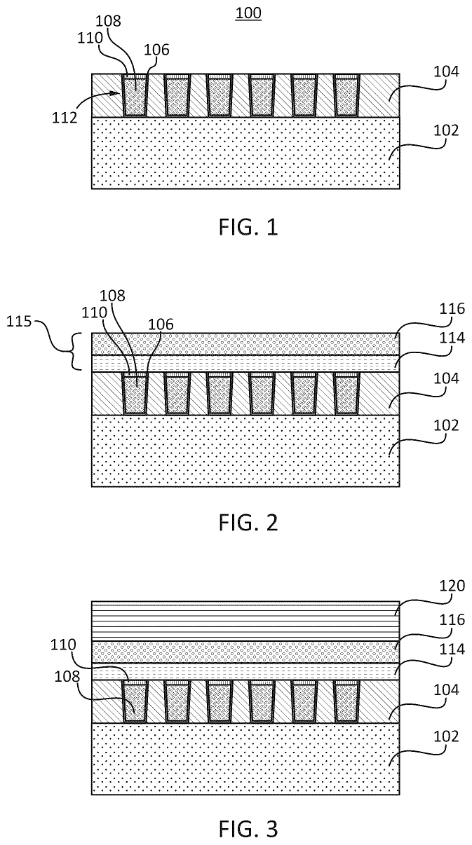

Referring now to the drawings in which like-numerals represent the same or similar elements and initially to FIG. 1, devices and methods for manufacturing a semiconductor device are shown in accordance with embodiments of the present invention. A wafer 100 includes a substrate 102 having one or more layers on which the semiconductor device will be fabricated. FIG. 1 depicts a cross-sectional view of the substrate 102.

The substrate 102 can include any suitable structure and can include a semiconductor material, e.g., a bulk semiconductor, a semiconductor-on-insulator (SOI), etc., and preferably includes a monocrystalline semiconductor. The substrate 102 can include a fabricated front end of line (FEOL) structure having field effect transistors, and other devices formed thereon. In addition, the substrate 102 can include middle of the line (MOL) contacts to connect the FEOL structures to back end of line (BEOL) metal structures through dielectric materials.

In one example, the substrate 102 can include a Si-containing semiconductor substrate. Illustrative examples of Si-containing semiconductor materials suitable for the semiconductor substrate can include, but are not limited to, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

The substrate 102 can be fabricated through the formation of MOL structures. However, it should be understood that the structures described herein can be included in any metallization for any device type. The metallization described herein can be included in BEOL structures, backside interconnect layers, far back end of the line (FBEOL) structures or any other structures having a plurality of metal line layers and at any position where skip vias can be employed.

A dielectric material 104 is formed on the wafer 100. The dielectric material 104 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric material 104 can be deposited using chemical vapor deposition (CVD), although other deposition methods can be employed.

The dielectric material 104 can be planarized to expose a top surface. The planarization process can include a chemical mechanical polishing (CMP) process.

The dielectric material 104 is patterned by forming a mask (not shown) that can include a patterned photoresist or other etch mask that can be applied to a surface of the dielectric material 104 and etched or developed to form the mask. An etch process is performed to remove the dielectric material 104 except portions protected by the mask to form trenches for the formation of metal lines. The etch process, such as e.g., reactive ion etching (RIE) or ion beam etching (IBE) or any suitable etch process selectively removes the dielectric material 104 relative to the mask. The mask can then be removed by a selective etch or polish process.

A liner 106 can include, e.g., TaN, TiN, Ru, or similar materials, and be deposited to line the trenches prior to a conductive fill. A conductive fill is performed to fill the trenches. The conductive fill can include materials, such as, e.g., Cu, Ru, Mo, Rh, W, Ir, and alloys or combinations of these and other conductive materials. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form metal lines 108 for a metal level 112, which can be referred to as metal level Mx.

A recess etch can be performed to recess the metal lines 108. The recess provides space to form caps 110, which can be deposited by a selective deposition process. The caps 110 can include a metal, such as, e.g., Co or other metal having a high conductivity.

Referring to FIG. 2, a first dielectric layer 114 is formed on the wafer 100. The first dielectric layer 114 can be blanket deposited over the wafer 100. The first dielectric layer 114 can be deposited using CVD, although other deposition methods can be employed. The first dielectric layer 114 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H).

A second dielectric layer 116 is formed on the first dielectric layer 114. The second dielectric layer 116 can be blanket deposited. The second dielectric layer 116 can be deposited using CVD, although other deposition methods can be employed. The second dielectric layer 116 can include a different material than that of the first dielectric layer 114. In this way, the second dielectric layer 116 and first dielectric layer 114 can be selectively etched relative to the other in later steps. The material for the second dielectric layer 116 can include a selectively etchable material relative to the first dielectric layer 114, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The second dielectric layer 116 can be planarized e.g., by CMP.

The first dielectric layer 114 and the second dielectric layer 116 can have a combined thickness of a via layer. In an embodiment, each of the first dielectric layer 114 and the second dielectric layer 116 can include about one half of the thickness of a via level 115, which can be referred to as Vx. Other proportions are also contemplated.

Referring to FIG. 3, an interlayer dielectric (ILD) 120 is formed on the second dielectric layer 116. The ILD 120 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 120 can be deposited using CVD, although other deposition methods can be employed.

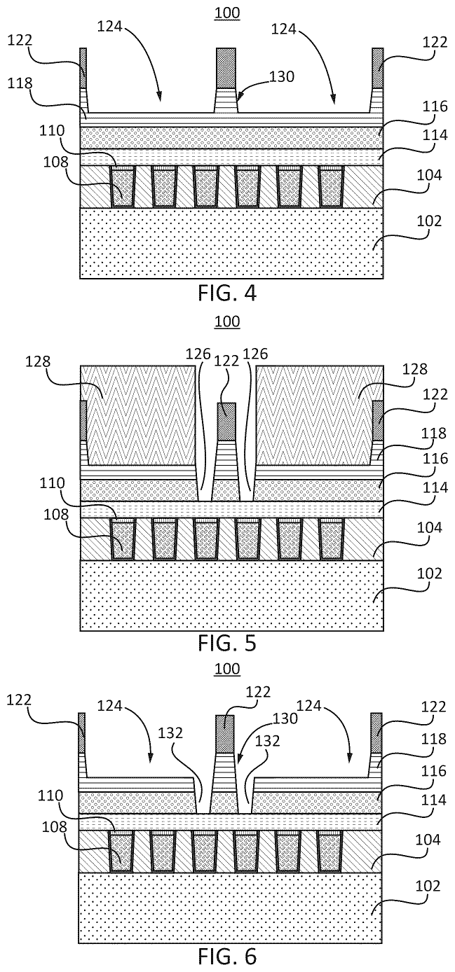

Referring to FIG. 4, the ILD 118 is patterned to form trenches 124 for metal lines to be formed. A hard mask 122 is then deposited, which is lithographically patterned. An anisotropic etch is performed to transfer the pattern of the hard mask 122 to the ILD 118 by, e.g., RIE. The ILD 118 is not fully removed in the trenches 124 and a dielectric pillar 130 separates adjacent trenches 124.

Referring to FIG. 5, a patternable material 128 is deposited or spun onto a surface of the wafer 100. In an embodiment, the patternable material 128 can include an organic planarization layer (OPL). The patternable material 128 can be patterned using a lithographic process. For example, a layer of photoresist can be formed on the patternable material 128. The layer of photoresist can be imaged with an image pattern and developed to form an etch mask. The patternable material 128 can be etched in accordance with the etch mask to open up trenches 126, which are self-aligned due to the presence of the hard mask 122. The trenches 126 locate vias that will be employed for connecting metal lines above and below the vias. The etching can include, e.g., RIE. The etching can continue to etch through the ILD 118 and the dielectric layer 116, stopping on the first dielectric layer 114. The patternable material 128 is then removed, e.g., by an ashing process, if OPL is employed.

Referring to FIG. 6, the second dielectric layer 116 can be employed as an etch mask to partially etch through the first dielectric layer 114 to form openings 132. This etch process is also self-aligned relying on the hard mask 122 and the etch selectivity difference between the second dielectric layer 116 and the first dielectric layer 114. The ILD 118 will be removed from bottoms of the trenches 124 to permit a full depth for metal lines to be formed.

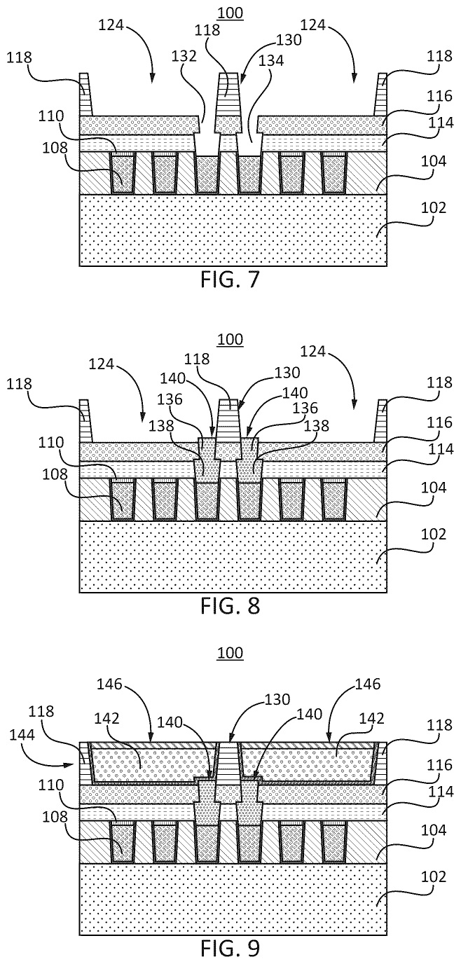

Referring to FIG. 7, via openings 134 are expanded through an etch process. The etch process can include an isotropic etch that selectively removes the first dielectric layer 114 without removing the second dielectric layer 116. The etch process accesses the first dielectric layer 114 through openings 132. The isotropic etch also removes the caps 110 in the openings 134. This exposes the conductive fill of the metal lines 108, which communicates with the openings 134. The isotropic etch can include a wet etch.

Referring to FIG. 8, a conductive deposition process is performed to deposit material to form vias 140. The metal lines 108 with the caps 110 removed provides a clean surface on which a selective deposition of a metal can be performed. The selective metal deposition can include the deposition of Ru, Co or other metals, alloys or combinations thereof. Selective deposition can be achieved by area-selective deposition (ASD), ALD or other suitable processes.

The deposition process fills the openings 132 and 134, which results in the formation of wider bottom portions 138 of the vias 140 that directly connects to the metal lines 108. A thinner top portion 136 conserves layout area on opposing sides of the dielectric pillar 130. In this way, additional space is provided to ensure that metal lines to be formed have adequate insulation between them.

The vias 140 can include linerless vias. Said differently, the vias 140 are formed without first depositing a diffusion barrier or other liner materials, ensuring a direct connection (less resistance) between the vias 140 and the underlying metal lines 108. In an embodiment, the top portion 136 of the vias 140 can extend partially into a next metal level (metal level 144, FIG. 9). The top portion 136 extending into the trenches 124 increases a surface area between the top portion 136 and the metal line 142 (FIG. 9) to be formed.

Referring to FIG. 9, a conductive deposition is performed over the wafer 100 to fill the trenches 124 and form a metal level 144. The conductive deposition can include materials, such as, e.g., Cu, Ru, Mo, Rh, W, Ir, and alloys or combinations of these and other conductive materials. In a particularly useful embodiment, the conductive deposition includes Cu. The conductive deposition can include, e.g., CVD, PECVD, ALD or any other suitable deposition method. The conductive deposition can be planarized, e.g., by CMP, to form metal lines 142. The metal lines 142 connect to the vias 140 at end portions 146 of the metal lines 142.

The metal lines 142 are formed on opposite sides of the dielectric pillar 130. The pillar 130, having been preformed, provides a predetermined and adequate width to reduce or eliminate the possibility of short circuits between the end portions 146.

The dielectric pillar 130 forms a zero track skip that acts as a break between portions of the metal line 142. Boundaries of the zero track skip are defined by the dielectric pillar 130 and the vias 140, which extend through different dielectric layers and materials where the zero track skip is located. A width of the dielectric pillar 130 includes a tip-to-tip distance that reduces short circuits between the end portions of the metal lines 142. In addition, the vias 140 are connected to the portions of the metal lines 108 at interfaces which occupy a larger surface area (on the top portions of the metal lines and bottoms or the wider bottom portions 138 of the vias 140). This improves resistance properties between the vias 140 and the metal lines 108. Processing can continue with the formation of additional components, which can include additional dielectric layers and metal structures.

Semiconductor devices can provide improved resistance characteristics between the metal lines 142 (and 108) and the vias 140. The vias 140 can include the wider bottom portion 138 at their bottom that directly contacts the top surface of the underlying metal lines 108. This wider bottom portion 138 may provide an increased contact area between the vias 140 and the metal lines 108, which may result in lower contact resistance.

In some cases, the removal of the caps 110 from the underlying metal lines prior to via formation may contribute to the improved resistance. This removal may expose a clean, unoxidized surface of the metal line, potentially allowing for better electrical contact between the vias 140 and the metal lines 108.

The use of linerless vias may also play a role in reducing resistance. By eliminating the diffusion barrier or liner materials typically used in via formation, a direct metal-to-metal contact may be achieved between the via and the underlying metal line. This direct contact may minimize interfacial resistance that could otherwise be introduced by intermediate layers.

The selective deposition process used to form the vias 140 may further enhance the electrical properties of the metal-to-metal interface. Selective deposition of materials such as Ru or Co may result in a high-quality, low-resistance connection between the vias 140 and the metal lines 108, 142. The increased surface area provided by extending the portion 136 into the metal lines 142 may also result in a high-quality, low-resistance connection between the vias 140 and the metal line 142.

In some embodiments, the combination of these factors, e.g., increased contact area, clean metal surfaces, direct metal-to-metal contact and high-quality selective deposition, can contribute to lowering the overall resistance between the metal lines and vias. This reduced resistance may lead to improved performance in the semiconductor device, potentially allowing for faster signal propagation and reduced power consumption.

The improved resistance characteristics may be particularly beneficial in advanced semiconductor nodes where resistance becomes an increasingly important factor in device performance. As dimensions shrink, the impact of contact resistance becomes more pronounced, making the resistance improvements achieved through this structure more significant.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods, as described herein, can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first metal level including first metal lines;
a second metal level including second metal lines; and
a via level between the first metal level and the second metal level, the via level including:
a first dielectric layer on the first metal lines;
a second dielectric layer on the first dielectric layer; and
vias having different widths respectively through the first dielectric layer and the second dielectric layer to connect the first metal lines to the second metal lines; and
wherein the second metal lines include end portions separated by a dielectric pillar, the dielectric pillar including a width between the end portions to reduce short circuits.

2. The semiconductor device of claim 1, wherein the vias include:
a top portion having a first width in the second dielectric layer; and
a bottom portion having a second width in the first dielectric layer, wherein the second width is greater than the first width.

3. The semiconductor device of claim 2, wherein the bottom portion directly contacts a top surface of one of the first metal lines.

4. The semiconductor device of claim 1, wherein the vias are linerless vias.

5. The semiconductor device of claim 1, wherein the vias include a top surface that extends partially into the second metal level.

6. The semiconductor device of claim 1, wherein the first dielectric layer and the second dielectric layer include different materials.

7. The semiconductor device of claim 1, wherein the vias include a selectively deposited metal.

8. A semiconductor device, comprising:
a first metal level including first metal lines;
a second metal level including second metal lines; and
a via level between the first metal level and the second metal level, the via level including:
a first dielectric layer on the first metal lines;
a second dielectric layer on the first dielectric layer; and
vias extending through the first dielectric layer and the second dielectric layer;
wherein the vias include:
a top portion in the second dielectric layer having a first width; and
a bottom portion in the first dielectric layer having a second width, the second width being greater than the first width; and
wherein the second metal lines include end portions separated by a dielectric pillar.

9. The semiconductor device of claim 8, wherein the dielectric pillar provides a width between the end portions to reduce short circuits.

10. The semiconductor device of claim 8, wherein the bottom portion directly contacts a top surface of one of the first metal lines.

11. The semiconductor device of claim 8, wherein the vias are linerless vias.

12. The semiconductor device of claim 8, wherein the vias include a top surface that extends partially into the second metal level.

13. The semiconductor device of claim 8, wherein the first dielectric layer and the second dielectric layer include different materials.

14. The semiconductor device of claim 8, wherein the vias include a selectively deposited metal.

15. A semiconductor device, comprising:
a first metal level including first metal lines;
a second metal level including second metal lines; and
a via level between the first metal level and the second metal level, the via level including:
a first dielectric layer on the first metal lines;
a second dielectric layer on the first dielectric layer; and
linerless vias extending through the first dielectric layer and the second dielectric layer;
wherein the linerless vias include:
a top portion in the second dielectric layer having a first width; and
a bottom portion in the first dielectric layer having a second width, the second width being greater than the first width and the bottom portion directly contacting a top surface of one of the first metal lines; and
wherein the second metal lines include end portions separated by a dielectric pillar, the dielectric pillar having a width between the end portions.

16. The semiconductor device of claim 15, wherein the linerless vias include a top surface that extends partially into the second metal level.

17. The semiconductor device of claim 15, wherein the first dielectric layer and the second dielectric layer include different materials.

18. The semiconductor device of claim 15, wherein the linerless vias include a selectively deposited metal.

19. The semiconductor device of claim 15, wherein the dielectric pillar is formed from an interlayer dielectric material.

20. The semiconductor device of claim 15, wherein the width of the dielectric pillar includes a tip-to-tip distance to reduce short circuits between the end portions of the second metal lines.
